(19) United States
(12) Patent Application Publication
(10) Pub. No.: US 2012/0063102 A1
(43) Pub. Date: Mar. 15, 2012

(54) Electronic Device, Circuit Board Assembly, and Semiconductor Device

(76) Inventors: Yasunari Ukita, Tokyo (JP); Kiyokazu Ishizaki, Tokyo (JP)

(21) Appl. No.: 13/082,217

(22) Filed: Apr. 7, 2011

(30) Foreign Application Priority Data
Sep. 15, 2010 (JP) 2010-207030

(51) Int. Cl. H05K 7/00

(52) U.S. Cl. 361/752

(57) ABSTRACT

According to one embodiment, an electronic device includes a housing, a circuit board, and a component. The circuit board is provided in the housing, and includes a first pad and a second pad exposed on the surface. The component includes a first electrode and a second electrode. The first electrode is exposed on the circuit board-facing surface of the component fading the surface of the circuit board and bonded to the first pad via a bonding agent. The second electrode is exposed on the circuit board-facing surface and bonded to the second pad via a bonding agent. The second electrode is wider than the first electrode and projects more than the first electrode does.

### CROSS-REFERENCE TO RELATED APPLICATIONS

This application is based upon and claims the benefit priority from Japanese Patent Application No. 2010-207030, filed Sep. 15, 2010, the entire contents of which are incorporated herein by reference.

### FIELD

Embodiments described herein relate generally to an electronic device, a circuit board assembly, and a semiconductor device.

### BACKGROUND

There have been known electronic devices provided with a circuit board assembly in the housing. The circuit board assembly includes a circuit board and components soldered on the surface of the circuit board.

It is required that, in such an electronic device, the components be bonded to the circuit board in a reliable condition.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of an electronic device according to an embodiment;

FIG. 2 is an exemplary cross-sectional view of a part of a circuit board assembly provided in the electronic device in the embodiment;

FIG. 3 is an exemplary cross-sectional view of a component (semiconductor device) provided in the circuit board assembly of FIG. 2 in the embodiment;

FIG. 4 is an exemplary plan view of the component of FIG. 3 viewed from a circuit board-facing surface in the embodiment;

FIGS. 5A to 5E are exemplary schematic diagrams illustrating a sequence of the manufacturing process of the circuit board assembly of FIG. 2 in the embodiment;

FIGS. 6A to 6F are exemplary cross-sectional views illustrating a sequence of the manufacturing process of the component of FIG. 3 in the embodiment;

FIG. 7 is an exemplary cross-sectional view of a modification of the component (semiconductor device) provided in the electronic device in the embodiment;

FIG. 8 is an exemplary cross-sectional view of a modification of the component (semiconductor device) provided in the electronic device in the embodiment;

FIG. 9 is an exemplary cross-sectional view of a part of a modification of the circuit board assembly provided in the electronic device in the embodiment; and

FIG. 10 is an exemplary plan view of a pad provided on a circuit board used in the modification of the circuit board assembly of FIG. 9.

### DETAILED DESCRIPTION

In general, according to one embodiment, an electronic device comprises a housing, a circuit board, and a component. The circuit board is provided in the housing, and comprises a first pad and a second pad exposed on the surface. The component cmprises a first electrode and a second electrode. The first electrode is exposed on the circuit board-facing surface of the component facing the surface of the circuit board and bonded to the first pad via a bonding agent. The second electrode is exposed on the circuit board-facing surface and bonded to the second pad via a bonding agent. The second electrode is wider than the first electrode and projects more than the first electrode does.

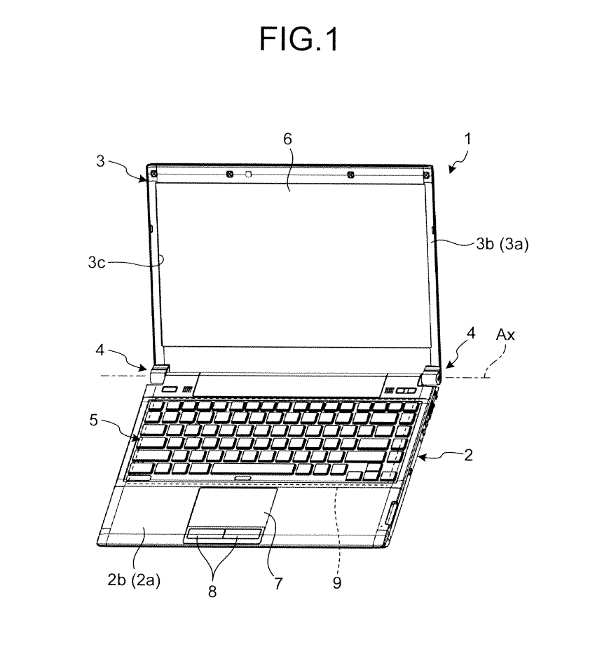

Exemplary embodiments will be described in detail below with reference to the accompanying drawings. As illustrated in FIG. 1, an electronic device 1 according to an embodiment may be, for example, a notebook personal computer, and comprises a flat rectangular first main body 2 and a flat rectangular second main body 3. The first main body 2 and the second main body 3 are connected in a relatively rotatable manner around a rotation axis Ax via a hinge portion 4 between an open position illustrated in FIG. 1 and a closed position (not illustrated).

The first main body 2 is provided with a keyboard 5, a pointing device 7, click buttons 8, and the like functioning as input devices exposed on a front face 2b as the external face of a housing 2a. The second main body 3 is provided with a display 6 as a display device such as a liquid crystal display (LCD). The display 6 is a component exposed from an opening 3c on a front face 3b as the external face of a housing 3a. In the open position as illustrated in FIG. 1, the keyboard 5, the display 6, the pointing device 7, the click buttons 8, and the like are exposed so that the user can use them. On the other hand, in the closed position (not illustrated), the front faces 2b and 3b closely face each other, and the keyboard 5, the display 6, the pointing device 7, the click buttons 8, and the like are hidden between the housings 2a and 3a.

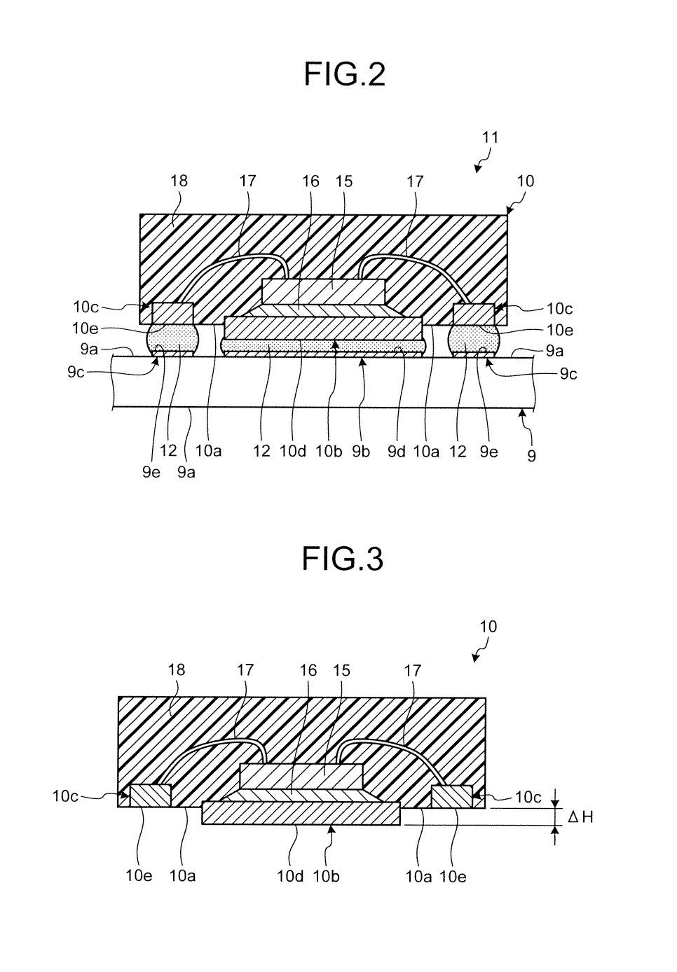

The housing 2a of the first main body 2 houses components such as a circuit board assembly 11, a hard disk (not illustrated), a cooling fan (not illustrated), and the like. The circuit board assembly 11 comprises a circuit board 9 having a central processing unit (CPU), a read only memory (ROM), a random access memory (RAM), and another component 10 (for example, see FIG. 2) mounted thereon.

As illustrated in FIG. 2, in the circuit board assembly 11, a component 10 is bonded to a surface 9a of the circuit board 9 (a printed circuit board) using a bonding agent 12 such as solder. Not only on the surface 9a on the upper side of the circuit board 9 may the component 10 be mounted, but the component 10 may also be mounted on the surface (rear face) 9a on the lower side of the circuit board 9. In addition, a conductive adhesive agent and the like, instead of solder, may be used as the bonding agent 12.

The component 10 illustrated in FIG. 2 is a surface mounted semiconductor device such as a land grid array (LGA) and a quad flat no lead package (QFN). As illustrated in FIG. 3, electrodes 10b and 10c are exposed on a rectangular (square) circuit board-facing surface 10a of the component 10 facing the surface 9a of the circuit board 9.

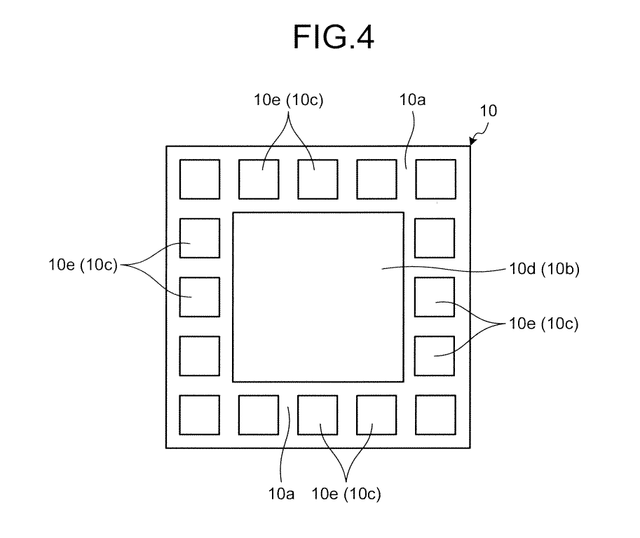

As illustrated in FIG. 4, the electrode 10b is formed in a rectangular shape and located at the center of the circuit board-facing surface 10a. The electrode 10b functions as a heat radiating electrode that radiates heat from the inside of the component 10 to the outside. The electrode 10b can also function as a ground electrode, but may not be used as the ground electrode. In the embodiment, the electrode 10b corresponds to the second electrode.

A plurality of electrodes 10c are exposed on a rectangular frame-shaped area between the side of the electrode 10b and the side of the circuit board-facing surface 10a. The electrodes 10c are located on both sides of the electrode 10b. The electrodes 10c are arranged to surround the periphery of the electrode 10b. The electrodes 10c each can function as a signal electrode, but some of them may not be used as signal electrodes. In the embodiment, the electrodes 10c correspond to the first electrode.

The electrodes 10b and 10c are bonded with the bonding agent 12 to pads 9b and 9c exposed on the surface 9a of the circuit board 9, respectively, to face each other. In the embodiment, the pad 9b corresponds to the second pad, and the pad 9c corresponds to the first pad.

As illustrated in FIGS. 2 to 4, in the embodiment, the area of the electrode 10b (the area of a bonding surface 10d) is larger than the area of the electrode 10c (the area of a bonding surface 10e). The electrode 10b projects toward the surface 9a of the circuit board 9 more than the electrode 10c does. More specifically, the flat bonding surface 10d, which is the top face of the electrode 10b, projects more than the flat bonding surface 10e, which is the top face of the electrode 10c, does. In the examples of FIGS. 2 and 3, the bonding surface 10e does not project from the circuit board-facing surface 10a but is in line with the circuit board-facing surface 10a.

Assuming that the projecting heights of the electrodes 10b and 10c are the same as in conventional technologies, if the bonding agent 12 is applied to the entire surfaces of the electrodes 10b and 10c to the same level, the volume of the bonding agent 12 for bonding the electrode 10b with the pad 9b becomes larger than the volume of the bonding agent 12 for bonding the electrode 10c with the pad 9c, as much as the area of the electrode 10b is larger than the area of the electrode 10c. In this case, the component 10 tends to shift and tilt due to the coagulation effect of the bonding agent 12 whose volume is relatively large and the like. Accordingly, the bonding state between the electrode 10c and the pad 9c fluctuates easily. For example, if the electrode 10c and the pad 9c are brought close to each other when the component 10 is tilted, the bonding agent 12 leaks out to the periphery of the electrode 10c and the pad 9c, thereby easily causing a short circuit with the adjacent electrode 10c or the pad 9c. If the electrode 10c and the pad 9c are separated from each other when the component 10 is tilted, the bonding agent 12 becomes insufficient, thereby easily causing a poor connection and no contact.

The shift and tilt of the component 10 described above can be easily eliminated by reducing the volume of the bonding agent 12 (volume per unit area of the electrode 10b) for bonding the electrode 10b with the pad 9b. However, the bonding agent 12 in a liquid state spreads along the bonding surface 10d of the electrode 10b and a bonding surface 9d of the pad 9b due to the surface tension (intermolecular force). Accordingly, a space between the electrode 10b and the pad 9b is filled with the bonding agent 12. At this time, the electrode 10b and the pad 9b are brought close to each other by the surface tension (intermolecular force) of the bonding agent 12. The more the size of the electrode 10c is reduced with the reduction of the size of the component 10, the more difficult to reduce the volume of the bonding agent 12 between the electrode 10c and the pad 9c, due to production yield and connection reliability. In this manner, if the volume of the bonding agent 12 (volume per unit area of the electrode 10b) for bonding the electrode 10b with the pad 9b is only reduced without reducing the volume of the bonding agent 12 (volume per unit area of the electrode 10c) for bonding the electrode 10c with the pad 9c, the electrode 10c and the pad 9c are brought too close to each other, because the electrode 10b and the pad 9b are brought close to each other by the surface tension (intermolecular force) of the bonding agent 12. Accordingly, the bonding agent 12 for bonding the electrode 10c with the pad 9c leaks out to the periphery, and a short circuit is likely to occur between the electrode 10c or the pad 9c, and the adjacent electrode 10c or the pad 9c.

In regard to this point, in the embodiment, as exemplified in FIGS. 2 and 3, the volume of the space between the electrode 10b and the pad 9b to be filled with the bonding agent 12 can be reduced by an amount by which the electrode 10b projects toward the surface 9a of the circuit board 9 more than the electrode 10c does. Accordingly, even when the volume of the bonding agent 12 (volume per unit area of the electrode 10b) for bonding the electrode 10b with the pad 9b is only reduced without reducing the volume of the bonding agent 12 (volume per unit area of the electrode 10c) between the electrode 10c and the pad 9c as described above, the distance obtained by summing up the thickness of the bonding agent 12 between the electrode 10b and the pad 9b, and the projecting height of the electrode 10b can be easily obtained between the electrode 10c and the pad 9c. As a result, it is possible to easily prevent the connection failure caused when the electrode 10c and the pad 9c are brought too close to each other as described above.

For the reasons described above, the electrode 10b projects toward the surface 9a of the circuit board 9 more than the electrode 10c does in the embodiment. In the embodiment, the distance between the bonding surface 10e of the electrode 10c and a bonding surface 9e of the pad 9c is longer than the distance between the bonding surface 10d of the electrode 10b and the bonding surface 9d of the pad 9b. In the embodiment, the bonding agent 12 bonding the electrode 10c to the pad 9c is thicker than the bonding agent 12 bonding the electrode 10b to the pad 9b. In the embodiment, the volume of the bonding agent 12 bonding the electrode 10c to the pad 9c per unit area of the electrode 10c is larger than the volume of the bonding agent 12 bonding the electrode 10b to the pad 9b per unit area of the electrode 10b.

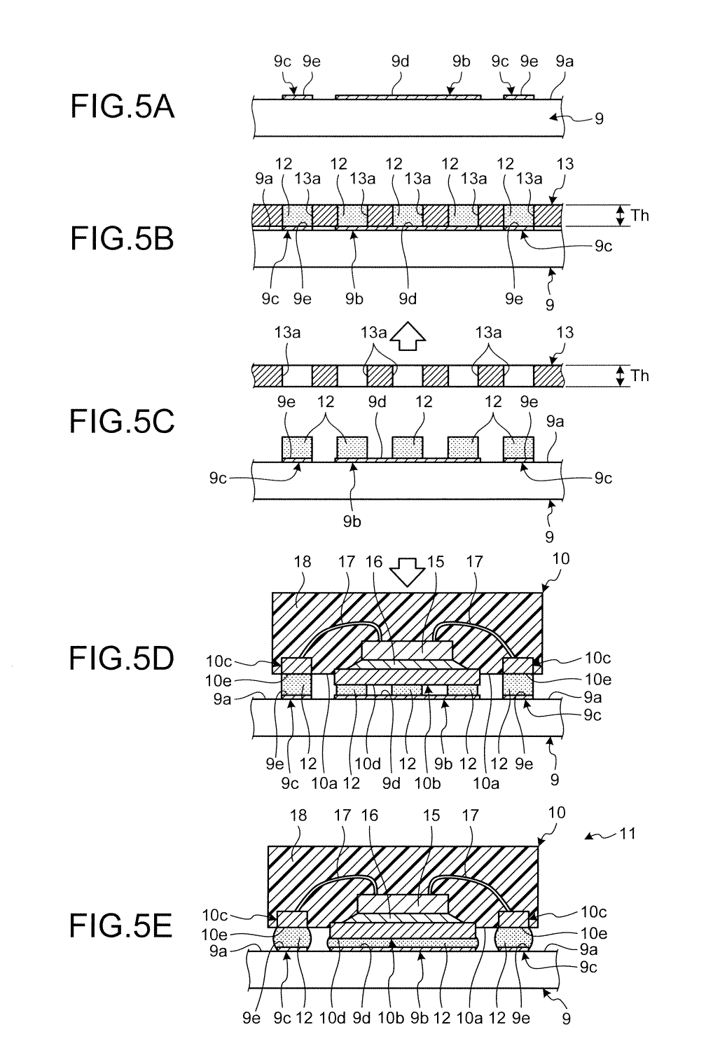

With reference to FIGS. 5A to 5E, how the circuit board assembly 11 of FIG. 2 is manufactured, i.e., how the component 10 is bonded to the circuit board 9 will be described.

As illustrated in FIG. 5A, the circuit board 9 having the surface 9a on which the pads 9b and 9c corresponding to the electrodes 10b and 10c of the component 10 are mounted is set at a predetermined position (circuit board setting process). As illustrated in FIG. 5B, a mask 13 in which through holes 13a are formed is then set on the surface 9a of the circuit board 9 (mask setting process). The mask 13 is formed in a plate-like shape whose thickness Th is constant. The through holes 13a are arranged on the pads 9b and 9c. The bonding agent 12 is filled into the through holes 13a with some degree of fluidity. At this time, the level of the bonding agent 12 filled into the through holes 13a is constant and is the same as the thickness Th of the mask 13 (bonding agent filling process). As illustrated in FIG. 5C, the mask 13 is then removed, thereby leaving the bonding agents 12 on the pads 9b and 9c. In this manner, the bonding agent 12 is applied on the pads 9b and 9c (bonding agent setting (applying) process). As illustrated in FIG. 5D, the component 10 is mounted on a predetermined position of the circuit board. 9 to which the bonding agent 12 is applied (component mounting process). Then, the circuit board assembly 11 illustrated in FIG. 5E and FIG. 2 is obtained, after reflow treatment is performed (reflow process) and cooled (solidifying process), while the component 10 is mounted on the circuit board 9 as in FIG. 5D.

In the examples of FIGS. 5A to 5E, the volume of the bonding agent 12 per unit area of the electrode 10b or 10c can be adjusted by the ratio of the opening area of each of the through holes 13a of the mask 13 relative to the areas Sb and Sc of the electrodes 10b and 10c (opening ratio αb and αc).

The volume Vb of the bonding agent 12 for bonding the electrode 10b with the pad 9b in the solidified state can be represented as follows:

Vb=αb×Sb×Th×β (1)

where β (V→β·V) is the variation rate of the volume during solidification due to the loss of volatile components and the like compared to that during the application of the bonding agent 12.

Accordingly, the volume Hb of the bonding agent 12 for bonding the electrode 10b with the pad 9b per unit area of the electrode 10b in the solidified state can be represented as follows:

Hb=Vb/Sb=αb×Th×β (2)

The volume Vc of the bonding agent 12 for bonding the electrode 10c with the pad 9c in the solidified state can be represented as follows:

Vc=αc×Sc×Th×β (3)

Accordingly, the volume Hc of the bonding agent 12 for bonding the electrode 10c with the pad 9c per unit area of the electrode 10c in the solidified state can be represented as follows:

Hc=Vc/Sc=αc×Th×β (4)

From studies conducted by the inventors, it was found that the bonding state of the bonding agent 12 for both the electrodes 10b and 10c is good if the difference ΔH between the projecting heights of the electrodes 10b and 10c (see FIG. 2) satisfies the following relation:

0.5(Hc−Hb)<ΔH<1.5(Hc−Hb) (5)

where (Hc−Hb) is the difference in the volume of the bonding agents 12 per unit area between the electrodes 10b and 10c.

It was also found that the bonding state is more preferable if the difference ΔH satisfies the following relation:

0.8(Hc−Hb)<ΔH<1.2(Hc−Hb) (6)

It was also found that the bonding state is especially good if the difference ΔH between the projecting heights of the electrodes 10b and 10c is closer to the difference (Hc−Hb) in height per unit area between the electrodes 10b and 10c, i.e., if the difference AH satisfies the following relation:

Hc−Hb≅ΔH (7)

or,

Hc−Hb=ΔH (8)

More specifically, ΔH is preferably from 10 to 150 micrometers, and more preferably from 20 to 80 micrometers. An opening ratio ac corresponding to the electrode 10c is preferably 1 (=100%).

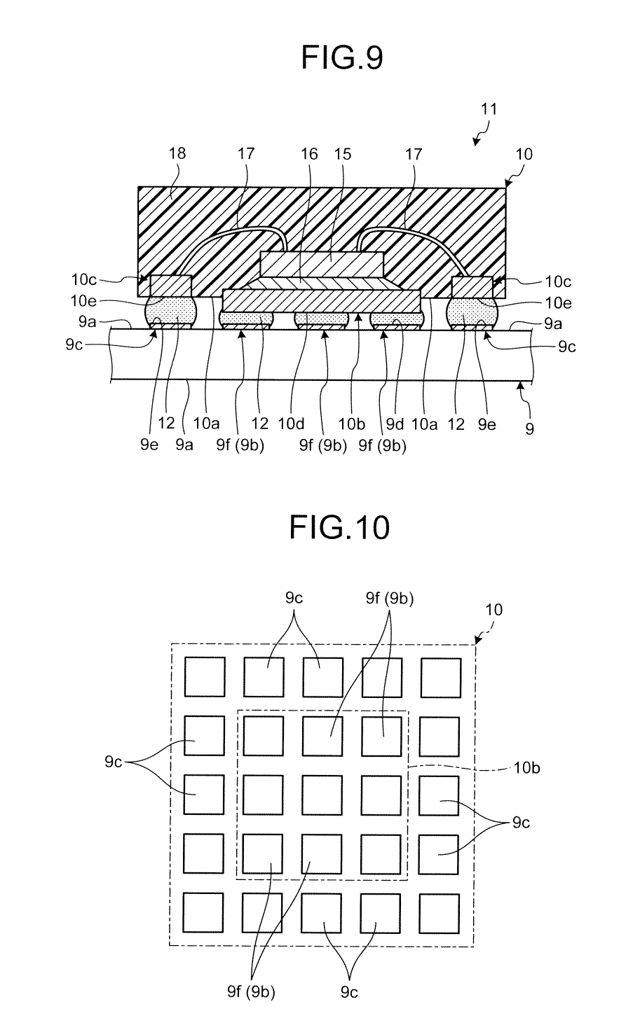

In a structure in which the pad 9b is divided into a plurality of pad portions 9f (see FIGS. 9 and 10), the area of the pad 9b sometimes become dominant. In such an event, the volume Vb of the bonding agent 12 for bonding the electrode 10b with the pad 9b in the solidified state can be represented as follows:

Vb=αb′×Sb′×Th×β (1)′

where Sb′ is the area of the pad 9b, and αb′ is the opening ratio of the through hole 13a of the mask 13 relative to the area of the pad 9b.

Accordingly, the volume Hb of the bonding agent 12 for bonding the electrode 10b with the pad 9b per unit area of the electrode 10b in the solidified state can be represented as follows:

Hb=Vb/Sb′=αb′×Th×β (2)′

In general, the bigger the volume of the bonding agent 12, the less likely voids are be formed. As illustrated in FIGS. 5A to 5E, voids in each bonding agent 12 can be reduced by dividing the bonding agent 12. However, voids may be left in the bonding agent 12, when air in the space between the divided bonding agents 12 is mixed into the bonding agent 12 and the like. In regard to this point, in the embodiment, the distance between the electrode 10b and the pad 9b is small as much as the electrode 10b projects compared to that when the electrode does not project. Accordingly, the bonding agent 12 spreads out easily (in the transverse direction of the drawing), and the air between the bonding agents 12 can be easily discharged.

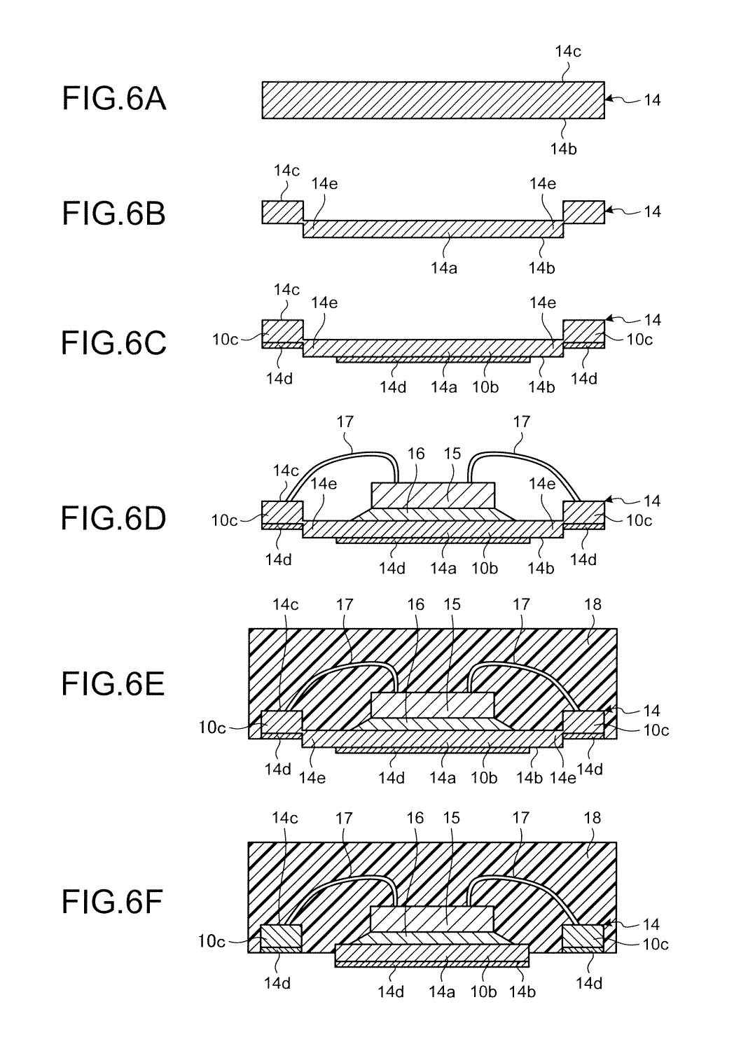

With reference to FIGS. 6A to 6F, how the component (semiconductor device) 10 of FIG. 3 is manufactured will be described.

A plate-like metal conductor (such as copper) 14 that is a base of a lead frame as illustrated in FIG. 6A is fabricated into a protrusion portion 14a (steps corresponding to the electrodes 10b and 10c) corresponding to the electrode 10b as illustrated in FIG. 6B. The protrusion portion 14a can be formed by pressing, cutting, etching, or the like (protrusion portion forming process and step-forming process).

As illustrated in FIG. 6C, a thin film (such as gold) 14d is selectively formed, for example, by plating on a lower surface 14b of the metal conductor 14, where the electrodes 10b and 10c are provided (electrode surface thin-film forming process).

As illustrated in FIG. 6D, a chip main body (die) 15 is mounted on an upper surface 14c of the metal conductor 14 via a bonding agent 16 (chip mounting process), and a signal pad (not illustrated) on the chip main body 15 and the electrode (terminal) 10c are bonded by a wire 17 (wire-bonding process).

As illustrated in FIG. 6E, the periphery of the metal conductor 14 on which the chip main body 15 is mounted is sealed by a sealing member 18 such as a molding agent and an underfilling agent comprising a synthetic resin material. In the example of FIG. 6E, the side above the chip main body 15 and the metal conductor 14 is mainly sealed, while the electrodes 10b and 10c and connection portions 14e thereof are exposed downward (sealing process).

As illustrated in FIG. 6F, the component 10 is then obtained after unnecessary portions such as the connection portions 14e of the metal conductor 14 are etched (etching process).

In this manner, the electrode 10b projects toward the circuit board 9 more than the electrode 10c does in the embodiment. Accordingly, in the circuit board assembly 11, a better bonding state can be obtained for both the bonding agent 12 for bonding the electrode 10c with the pad 9c and the bonding agent 12 for bonding the electrode 10b with the pad 9b, when the thickness of the bonding agent 12 for bonding the electrode 10c with the pad 9c is larger than the thickness of the bonding agent 12 for bonding the electrode 10b with the pad 9b, as well as when the volume Hc of the bonding agent 12 for bonding the electrode 10c with the pad 9c per unit area of the electrode 10c is larger than the volume Hb of the bonding agent 12 for bonding the electrode 10b with the pad 9b per unit area of the electrode 10b.

The electrode 10b projects from the circuit board-facing surface 10a in the embodiment. Accordingly, the bonding agent 12 can be spread to the side surface of the electrode 10b, thereby improving the bonding strength (durability, impact resistance, and the like).

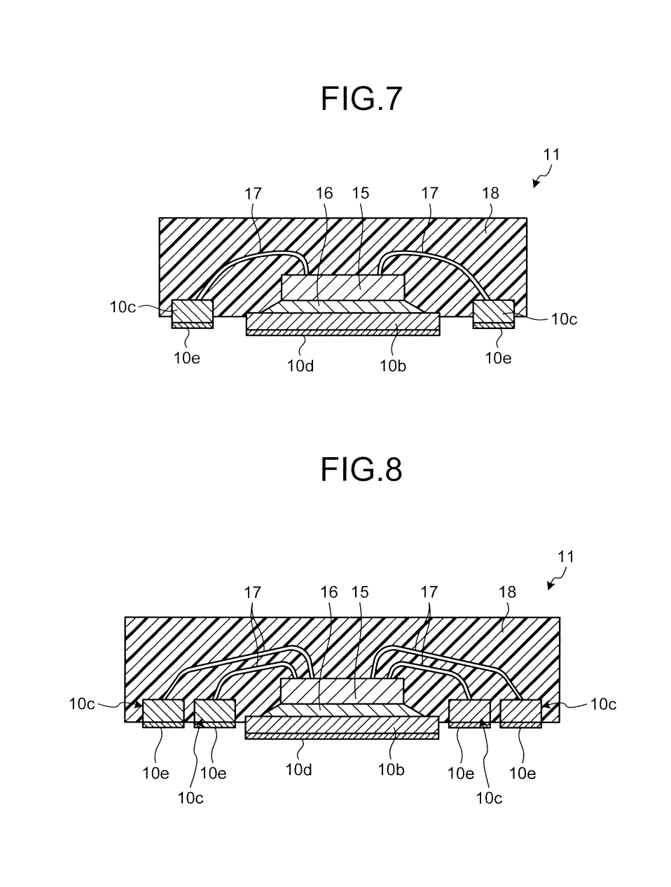

The embodiment is susceptible to various modifications and variations. For example, as illustrated in FIG. 7, not only the electrode 10b but also the electrode 10c may project from the circuit board-facing surface 10a. In this case, because the electrode 10c projects from the circuit board-facing surface 10a, the bonding agent 12 can be spread to the side surface of the electrode 10c. Accordingly, it is also possible to improve the bonding strength (durability, impact resistance, and the like) the bonding agent 12 for bonding the electrode 10c with the pad 9c.

The layout, the number, the size, the shape, and the like of the electrode 10c can be suitably modified. For example, as illustrated in FIG. 8, the electrodes 10c may be arranged annularly in a plurality of rows around the electrode 10b. In such a structure, the similar effects as those of the embodiment can be achieved.

For example, as illustrated in FIGS. 9 and 10, the pad 9b may have the pad portions 9f separated from each other on the surface 9a of the circuit board 9. The pad portions 9f are electrically connected with each other, and function as one pad 9b (in other words, the heat radiating electrode and the ground electrode). The pad 9b can be divided into the pad portion 9f, for example, by applying solder resist or the like on the surface side of the pad 9b. As an example, as illustrated in FIG. 10, the pad portions 9f can be arranged in an array. In the structure in which the pad 9b has the pad portions 9f, the spreading force of the bonding agent 12 for bonding the electrode 10b with the pad 9b can be reduced, as much as the area of the pad 9b is reduced, and the spreading area can be limited. Accordingly, it is possible to prevent the component 10 from shifting and tilting, thereby improving the bonding states between the electrode 10b and the pad 9b, and the electrode 10c and the pad 9c, via the bonding agent 12.

While the electronic device of the embodiment is described above as a notebook personal computer, it may also be any other electronic device. Examples of such electronic device includes the main body of desktop personal computers, hard disk drives (HDDs), personal digital assistants (PDAs), smartbooks, smartphones, cellular phones, display devices, or television devices.

The state where the distance between the first electrode and the first pad is larger than the distance between the second electrode and the second pad can also be obtained by a structure in which the second pad projects toward the component more than the first pad does. In such a structure, the thickness of the bonding agent for bonding the first electrode with the first pad can be made thicker than the thickness of the bonding agent for bonding the second electrode with the second pad. The volume of the bonding agent for bonding the first electrode with the first pad per unit area of the first electrode can be made larger than the volume of the bonding agent for bonding the second electrode with the second pad per unit area of the second electrode. Accordingly, the similar effects as those of the embodiment can be obtained. The similar effects can also be obtained in a structure in which the second pad projects toward the component more than the first pad does, and the second electrode projects toward the circuit board more than the first electrode does.

The specifications (structure, shape, material, size, length, width, thickness, number, arrangement, position, etc.) can be suitably modified regarding the electronic device, the housing, the circuit board assembly, the circuit board, the component, the electrode, the pad, the pad portion, the bonding agent, and the surface.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a housing;
a circuit board provided in the housing, the circuit board comprising a first pad and a second pad exposed on a surface; and
a component comprising
a first electrode exposed on a circuit board-facing surface facing the surface of the circuit board and bonded to the first pad via a bonding agent, and
a second electrode exposed on the circuit board-facing surface and bonded to the second pad via a bonding agent, the second electrode being wider than the first electrode and projecting more than the first electrode does.

2. The electronic device of claim 1, wherein the bonding agent bonding the first electrode to the first pad is thicker than the bonding agent bonding the second electrode to the second pad.

3. The electronic device of claim 1, wherein the second pad comprises a plurality of pad portions separated from each other on the surface.

4. The electronic device of claim 1, wherein the first electrode and the second electrode project from the circuit board-facing surface.

5. The electronic device of claim 1, wherein
the first electrode is a signal electrode, and
the second electrode is a heat radiating electrode.

6. The electronic device of claim 1, wherein volume of the bonding agent bonding the first electrode to the first pad per unit area of the first electrode to which the bonding agent is applied is larger than volume of the bonding agent bonding the second electrode to the second pad per unit area of the second electrode to which the bonding agent is applied.

7. The electronic device of claim 6, wherein 0.5(Hc−Hb)<ΔH<1.5(Hc−Hb) is satisfied where
ΔH is a difference in projecting height between the first electrode and the second electrode,
Hc is the volume of the bonding agent bonding the first electrode to the first pad per unit area of the first electrode to which the bonding agent is applied, and
Hb is the volume of the bonding agent bonding the second electrode to the second pad per unit area of the second electrode to which the bonding agent is applied.

8. An electronic device comprising:
a housing;
a circuit board provided in the housing, the circuit board comprising a first pad and a second pad exposed on a surface; and
a component comprising
a first electrode bonded to the first pad via a bonding agent, and
a second electrode bonded to the second pad via a bonding agent, wherein
a first distance between the first electrode and the first pad bonded to the first electrode via the bonding agent is larger than a second distance between the second electrode and the second pad bonded to the second electrode via the bonding agent.

9. A circuit board assembly comprising:
a circuit board comprising a first pad and a second pad exposed on a surface; and
a component comprising
a first electrode exposed on a circuit board-facing surface facing the surface of the circuit board and bonded to the first pad via a bonding agent, and
a second electrode exposed on the circuit board-facing surface and bonded to the second pad via a bonding agent, the second electrode being wider than the first electrode, and projecting toward the circuit board more than the first electrode does.

10. A semiconductor device comprising:
a first electrode exposed on a surface facing a circuit board; and
a second electrode exposed on the surface facing the circuit board, the second electrode being wider than the first electrode, and projecting more than the first electrode does.
